(19) United States
(12) Patent Application Publication
(10) Pub. No.: US 2016/0216698 A1
(43) Pub. Date: Jul. 28, 2016

(54) CONTROL OF ELECTRIC POWER CONSUMPTION

(71) Applicant: Empire Technology Development LLC, Wilmington, DE (US)

(72) Inventors: Naofumi YOSHIDA, Yokohama-shi (JP); Shuichi KURABAYASHI, Fujisawa-shi (JP); Kosuke TAKANO, Naka-gun (JP)

(21) Appl. No.: 14/398,014

(22) PCT Filed: Jul. 26, 2013
(86) PCT No.: PCT/US2013/052157

§ 371 Date: Oct. 30, 2014

(51) Int. Cl. G05B 13/02; G01R 22/06

(52) U.S. Cl. CPC G05B 13/02; G01R 22/061

(57) ABSTRACT

Technologies are generally described for an electric power consumption control scheme. In some examples, a method performed under control of a power control system may include measuring an electric power consumption of an electric device; obtaining a pattern of time-series change in the electric power consumption; and determining a type of the electric device based at least in part on the obtained pattern of time-series change in the electric power consumption.

### BACKGROUND

Technological advancement gives rise to a multitude of electric appliances, such as air conditioners, stereo systems, computers, digital televisions and the like. Although these electric appliances can bring a lot of convenience to the quality of human life, the resulting electric power consumption thereof continuously escalates. Despite power-saving features addressed by the improved new generation of electric appliances, many conventional electric appliances having high electric power consumption are ubiquitous in everyone's daily life.

### SUMMARY

In an example, a method performed under control of a power control system may include measuring an electric power consumption of an electric device; obtaining a pattern of time-series change in the electric power consumption; and determining a type of the electric device based at least in part on the obtained pattern of time-series change in the electric power consumption.

In another example, a power control system may include an electric power measuring unit configured to measure an electric power consumption of an electric device; a power consumption pattern obtaining unit configured to obtain a pattern of time-series change in the electric power consumption; and a device type determining unit configured to determine a type of the electric device based at least in part on the obtained pattern of time-series change in the electric power consumption.

In yet another example, a computer-readable storage medium may store thereon computer-executable instructions that, in response to execution, cause a power control system to perform operations including measuring an electric power consumption of an electric device; obtaining a pattern of time-series change in the electric power consumption; and determining a type of the electric device based at least in part on the obtained pattern of time-series change in the electric power consumption.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGURES

The foregoing and other features of this disclosure will become more fully apparent from the following description and appended claims, taken in conjunction with the accompanying drawings. With the understanding that these drawings depict only several embodiments in accordance with the disclosure and are, therefore, not to be considered limiting of its scope, the disclosure will be described with additional specificity and detail through use of the accompanying drawings, in which:

FIG. 1 schematically shows an illustrative example of an electric power control environment including a power control system, a cloud system, a first electric device, a second electric device and a third electric device, arranged in accordance with at least some embodiments described herein;

FIG. 2 shows examples of patterns of time-series change in electric power consumption, arranged in accordance with at least some embodiments described herein;

FIG. 3 shows an example of a priority class table, arranged in accordance with at least some embodiments described herein;

FIG. 4 shows a schematic block diagram illustrating an example architecture for a power control system, arranged in accordance with at least some embodiments described herein;

FIG. 5 shows an example flow diagram of a process of a power control system for controlling electric power consumption, arranged in accordance with at least some embodiments described herein;

FIG. 6 illustrates computer program products that may be utilized to provide a scheme for controlling electric power consumption, arranged in accordance with at least some embodiments described herein; and

FIG. 7 is a block diagram illustrating an example computing device that may be utilized to provide a scheme for controlling electric power consumption, arranged in accordance with at least some embodiments described herein.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

This disclosure is generally drawn, inter alia, to methods, apparatuses, systems, devices, and computer program products related to schemes for controlling electric power consumption. Technologies are generally described for determining a type of an electric device based on a pattern of electric power consumption which is measured from the electric device and controlling the electric power consumption according to the type of the electric device.

In some examples, a power control system may measure electric power consumption of each electric device in the vicinity of the power control system by using one or more wattmeters. The electric power consumption of each electric device may have a pattern of time-series change. For example, the electric power consumption may be changed like a sine wave as the time goes, or may be changed like a rectangular pulse. The power control system may calculate and obtain the pattern of time-series change from the measured electric power consumption.

Further, the power control system may determine a type of the electric device based at least in part on the obtained pattern of time-series change in the electric power consumption. For example, the power control system may compare the obtained pattern of time-series change of the electric device with at least one reference power consumption pattern and determine the type of the electric device based on a result of the comparison. The at least one reference power consumption pattern may be pre-registered and stored in a local memory of the power control system or a cloud system that is communicatively coupled to the power control system in association with at least one reference electric device type.

Upon determining the type of the electric device, the power control system may determine a priority class of the electric device regarding electric power consumption control based at least in part on the determined type of the electric device. For example, a lookup table that shows multiple reference priority classes and multiple types of electric devices which correspond to each of the multiple reference priority classes are prepared and stored in the local memory or the cloud system. The power control system may determine the priority class of the electric device from the multiple reference priority classes based on the determined type of the electric device. Then, when the power control system receives a request to control the electric power consumption of the electric device from a user of the end device or an owner/entity of an electric power supplier, the power control system may control the electric power consumption of the electric device based on the determined priority class of the electric device.

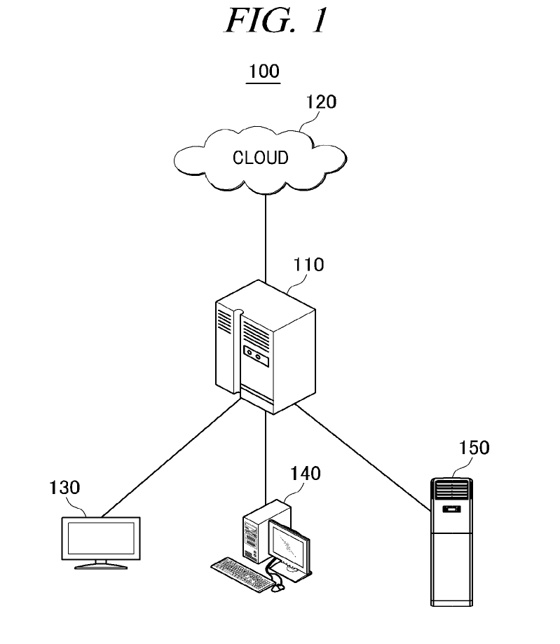

FIG. 1 schematically shows an illustrative example of an electric power control environment 100 including a power control system 110, a cloud system 120, a first electric device 130, a second electric device 140 and a third electric device 150.

Power control system 110 may refer to an apparatus or a device that may be configured to determine types of multiple electric devices based on patterns of time-series change of electric power consumption and control electric power consumption of the multiple electric devices based on the types of the multiple electric devices. Each of multiple power control systems including power control system 110 may be installed in a separated space, such as each house or each office and control electric power consumption of the multiple electric devices within the each separated space.

Cloud system 120 may refer to a cloud server or a cloud configuration that provides some type of communications, data storage, data or information processing, or any combination thereof.

First electric device 130, second electric device 140 and third electric device 150 may refer to all kinds of electric device that receive electric power from at least one electric power supplier and consume the supplied electric power. By way of example, but not limitation, first electric device 130, second electric device 140 and third electric device 150 may respectively include a laptop computer, a notebook computer, a mobile device, a television, a refrigerator, a microwave, an air conditioner, etc.

In some embodiments, power control system 110 may be connected to first electric device 130, second electric device 140 and third electric device 150 via a network. By way of example, but not limitation, the network between power control system 110 and each of first electric device 130, second electric device 140 and third electric device 150 may include a wired network such as LAN (Local Area Network), WAN (Wide Area Network), VAN (Value Added Network) or the like, or all kinds of wireless network such as a mobile radio communication network, a satellite network, a bluetooth, WiBro (Wireless Broadband Internet), Mobile WiMAX, HSDPA (High Speed Downlink Packet Access) or the like. Although FIG. 1 illustrates that three electric devices (i.e., first electric device 130, second electric device 140, third electric device 150) are connected to power control system 110, one skilled in the art will appreciate that any number of electric devices can be connected to power control system 110.

Power control system 110 may be configured to measure electric power consumption of first electric device 130, second electric device 140 and third electric device 150 by using any well-known electric power consumption measuring device such as a wattmeter. Power control system 110 may be further configured to calculate and obtain a pattern of time-series change in the measured electric power consumption of each electric device 130, 140, 150. The electric power consumption of each electric device 130, 140, 150 may have a time-series changed pattern.

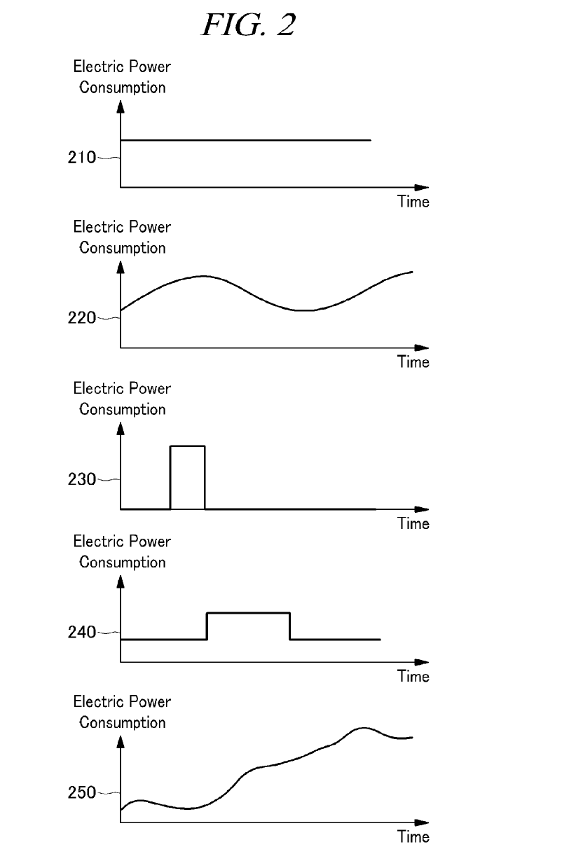

FIG. 2 shows examples of patterns of time-series change in the electric power consumption, arranged in accordance with at least some embodiments described herein. By way of example, but not limitation, as depicted in FIG. 2, a first pattern 210 may show a flat-typed pattern of electric power consumption, which may be obtained from a router, etc. A second pattern 220 may show a wave signal-typed pattern of electric power consumption, which may be obtained from a refrigerator, etc. A third pattern 230 may show a rectangular pulse-typed pattern of electric power consumption, which may be obtained from a microwave, etc. Further, a fourth pattern 240 may show an environment dependent pattern of electric power consumption, which may be obtained from an air conditioner, etc. For example, fourth pattern 240 may show a pattern which indicates that the electric power consumption during a certain time period (e.g., day time) is higher than the electric power consumption during other time period (e.g., night time). Further, a fifth pattern 250 may show a non-periodic and complex pattern of electric power consumption, which may be obtained from a projector, etc.

Referring back to FIG. 1, in some embodiments, power control system 110 may be further configured to store the obtained patterns of time-series change in electric power consumption of each electric device 130, 140, 150 in a local memory of power control system 110 as reference power consumption patterns. The reference power consumption patterns may refer to electric power consumption patterns which are pre-registered in association with each type of multiple electric devices. Accordingly, information regarding the reference power consumption patterns may be updated in the local memory of power control system 110.

Alternatively, power control system 110 may be further configured to store the obtained pattern of time-series change in electric power consumption of each electric device 130, 140, 150 in cloud system 120. Power control system 110 may be configured to transmit the obtained pattern of time-series change in electric power consumption to cloud system 120 via a wireless network such as LAN (Local Area Network), WAN (Wide Area Network), VAN (Value Added Network) or the like, or all kinds of wireless network such as a mobile radio communication network, a satellite network, a bluetooth, WiBro (Wireless Broadband Internet), Mobile WiMAX, HSDPA (High Speed Downlink Packet Access) or the like. Accordingly, the information regarding the reference power consumption pattern may be updated in cloud system 120. Cloud system 120 may be configured to receive the pattern of time-series change in electric power consumption from multiple power control systems including power control system 110, so, larger amount of the information regarding the reference power consumption pattern may be stored than each of power control system 110.

Further, cloud system 120 may be configured to transmit, to power control system 110, the information regarding the reference power consumption pattern, which is stored in cloud system 120. Then, power control system 110 may be configured to receive the information regarding the reference power consumption pattern from cloud system 120 and update the information in the local memory of power control system 110.

Further, power control system 110 may be configured to estimate and determine a type of each electric device 130, 140, 150 based at least in part on the obtained pattern of time-series change in the electric power consumption which is measured from each electric device 130, 140, 150. In some embodiments, power control system 110 may be configured to compare the obtained pattern of time-series change in electric power consumption with the reference power consumption patterns stored in the local memory of power control system 110. Then, power control system 110 may be configured to determine the type of each electric device 130, 140, 150, which is associated with the reference power consumption pattern corresponding to the obtained pattern of time-series change in electric power consumption of each electric device 130, 140, 150.

In some other embodiments, the reference power consumption patterns may be pre-registered and stored in cloud system 120 in association with at least one electric device type. Power control system 110 may be configured to determine the type of each electric device 130, 140, 150 by comparing the obtained pattern of time-series change in electric power consumption with the reference power consumption patterns stored in cloud system 120.

In some other embodiments, first, power control system 110 may be configured to determine the type of each electric device 130, 140, 150 by comparing the obtained pattern of time-series change in electric power consumption with the reference power consumption patterns stored in the local memory of power control system 110. If power control system 110 fails to determine the type of each electric device 130, 140, 150, power control system 110 may be configured to compare the obtained pattern of time-series change in electric power consumption with the reference power consumption patterns stored in cloud system 120. Further, power control system 110 may be configured to receive, from cloud system 120, information regarding the reference power consumption pattern that corresponds to the obtained pattern of time-series change in electric power consumption and add the received reference power consumption pattern in the local memory of power control system 110. Accordingly, the information regarding the reference power consumption patterns may be updated in the local memory of power control system 110.

Further, power control system 110 may be configured to determine a priority class of each electric device 130, 140, 150 regarding power consumption control based at least in part on the determined type of each electric device 130, 140, 150 and reference priority classes. In some embodiments, multiple reference priority classes regarding power consumption control may be prepared and pre-registered in the local memory of power control system 110 or cloud system 120. Each of the multiple reference priority classes may correspond to at least one electric device type and be associated with the at least one electric device type.

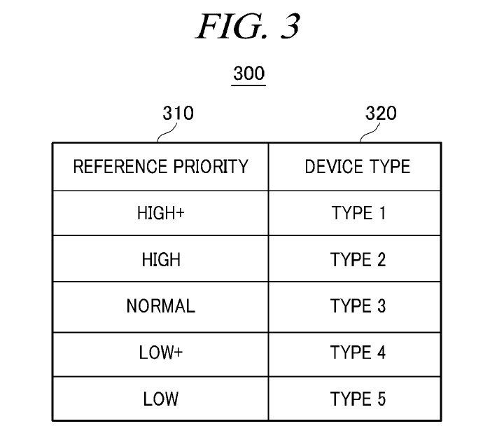

FIG. 3 shows an example of a priority class table 300, arranged in accordance with at least some embodiments described herein. By way of example, but not limitation, as depicted in FIG. 3, priority class table 300 may include a reference priority field 310 and a device type field 320. Reference priority field 310 may include five reference priority classes, e.g., ‘high+priority’, ‘high priority’, ‘normal priority’, ‘low+priority’ and ‘low priority’. Device type field 320 may include five device types, each of which is associated with each of the five reference priority classes.

By way of example, but not limitation, the ‘high+priority’ class may correspond to a type 1 of an electric device such as a medical device, which requires using electric power continuously. The ‘high priority’ class may correspond to a type 2 of an electric device such as a communication device, which requires using electric power as long as electric power is supplied. The ‘normal priority’ class may correspond to a type 3 of an electric device such as an air conditioner, which permits to reduce electric power consumption. The ‘low+priority’ class may correspond to a type 4 of an electric device such as a game machine, or a refrigerator, which permits interruption of electric power consumption for a certain period according to a user's notification. The ‘low priority’ class may correspond to a type 5 of an electric device such as an illumination, which permits to stop supplying electric power.

By way of example, it may be assumed that first electric device 130 is a medical device and second electric device 140 is a lighting stand. If power control system 110 determines the type of first electric device 130 as a medical device which corresponds to the type 1, power control system 110 may determine the priority class of first electric device 130 as the ‘high+priority’. Further, if power control system 110 determines the type of second electric device 140 as a lighting stand which corresponds to the type 5, power control system 110 may determine the priority class of second electric device 140 as the ‘low priority’.

Referring back to FIG. 1, power control system 110 may be further configured to receive a request to control electric power consumption of each electric device 130, 140, 150. By way of example, but not limitation, power control system 110 may receive a request to control electric power consumption of each electric device 130, 140, 150 from a user (not shown) who owns or other exercises control over an embodiment of each electric device 130, 140, 150 or an electric power supplier (not shown).

Then, power control system 110 may be further configured to control electric power consumption based at least in part on the determined priority class of each electric device 130, 140, 150. According to the above example, when power control system 110 receives a request to control electric power consumption, power control system 110 may be configured to keep on supplying electric power to first electric device 130 since power control system 110 determined the priority class of first electric device 130 as ‘high+priority’. Further, power control system 110 may be configured to stop to supply electric power to second electric device 140 since power control system 110 determined the priority class of second electric device 140 as ‘low priority’ depicted in FIG. 3 . By way of example, but not limitation, the electric power consumption of each electric device 130, 140, 150 may be controlled by using a remote controller that is registered and communicatively coupled to power control system 110 or by a hand.

In some other embodiments, a priority class regarding power consumption control may be pre-registered and provided to each electric device 130, 140, 150. Accordingly, if power control system 110 determines the type of each electric device 130, 140, 150, power control system 110 may be configured to control electric power consumption of each electric device 130, 140, 150 based on the pre-registered priority class of each electric device 130, 140, 150.

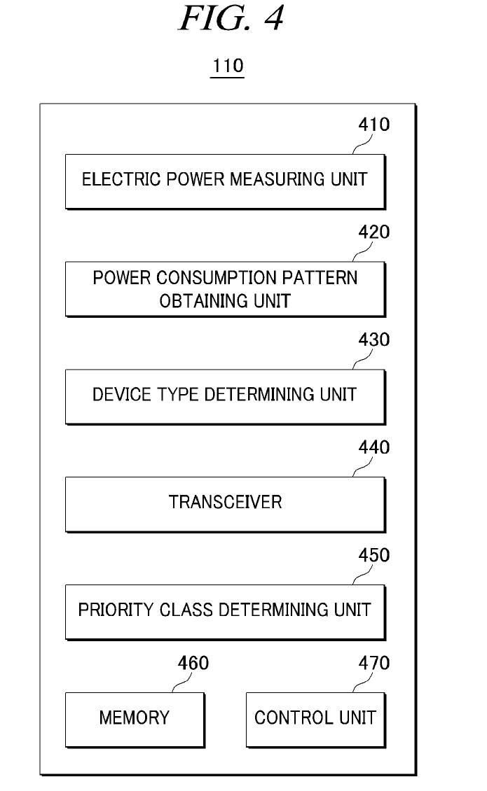

FIG. 4 shows a schematic block diagram illustrating an example architecture for power control system 110, arranged in accordance with at least some embodiments described herein. As depicted in FIG. 4, power control system 110 may include an electric power measuring unit 410, a power consumption pattern obtaining unit 420, a device type determining unit 430, a transceiver 440, a priority class determining unit 450, a memory 460 and a control unit 470. Although illustrated as discrete components, various components may be divided into additional components, combined into fewer components, or eliminated altogether while being contemplated within the scope of the disclosed subject matter. It will be understood by those skilled in the art that each function and/or operation of the components may be implemented, individually and/or collectively, by a wide range of hardware, software, firmware, or virtually any combination thereof. In that regard, one or more of electric power measuring unit 410, power consumption pattern obtaining unit 420, device type determining unit 430, transceiver 440, priority class determining unit 450, memory 460 and control unit 470 may be included in an instance of an application hosted on power control system 110.

Electric power measuring unit 410 may be configured to measure electric power consumption of an electric device. In some embodiments, electric power measuring unit 410 may include any-well known electric power consumption measuring device that outputs electric power consumption values, such as a wattmeter.

Power consumption pattern obtaining unit 420 may be configured to calculate and obtain a pattern of time-series change in the measured electric power consumption of the electric device. The electric power consumption of the electric device may have various types of time-series changed patterns. Non-limiting examples of the time-series changed patterns may include a flat-typed pattern of electric power consumption, which may be obtained from a router, etc, a wave signal-typed pattern of electric power consumption, which may be obtained from a refrigerator, etc, a rectangular pulse-typed pattern of electric power consumption, which may be obtained from a microwave, etc, an environment dependent pattern of electric power consumption, which may be obtained from an air conditioner, etc, or a non-periodic and complex pattern of electric power consumption, which may be obtained from a projector, etc.

Device type determining unit 430 may be configured to determine a type of the electric device based at least in part on the obtained pattern of time-series change in the electric power consumption. In some embodiments, device type determining unit 430 may be configured to compare the obtained pattern of time-series change in the electric power consumption with at least one reference power consumption pattern stored in memory 460. Such an electric power consumption pattern may be referred to as the at least one reference power consumption pattern, which is pre-registered in association with at least one type of an electric device. Device type determining unit 430 may be configured to determine the type of the electric device, which is associated with the at least one reference power consumption pattern corresponding to the obtained pattern of time-series change in the electric power consumption.

In some other embodiments, at least one reference power consumption pattern may be pre-registered and stored in cloud system 120 in association with at least one electric device type. Device type determining unit 430 may be configured to determine the type of the electric device by comparing the obtained pattern of time-series change in the electric power consumption with the at least one reference power consumption pattern stored in cloud system 120.

In some other embodiments, first device type determining unit 430 may be configured to determine the type of the electric device by comparing the obtained pattern of time-series change in the electric power consumption with the at least one reference power consumption pattern stored in memory 460. If device type determining unit 430 fails to determine the type of the electric device, then device type determining unit 430 may be configured to compare the obtained pattern of time-series change in the electric power consumption with the at least one reference power consumption pattern stored in cloud system 120.

Transceiver 440 may be configured to transmit the obtained pattern of time-series change in the electric power consumption to cloud system 120 via a wireless network such as LAN (Local Area Network), WAN (Wide Area Network), VAN (Value Added Network) or the like, or all kinds of wireless network such as a mobile radio communication network, a satellite network, a bluetooth, WiBro (Wireless Broadband Internet), Mobile WiMAX, HSDPA (High Speed Downlink Packet Access) or the like. Then, cloud system 120 may be configured to receive and store the obtained pattern of time-series change in the electric power consumption as the reference power consumption pattern.

Transceiver 440 may be further configured to receive, from cloud system 120, the reference power consumption pattern stored in cloud system 120.

Priority class determining unit 450 may be configured to determine a priority class of the electric device regarding a power consumption control based at least in part on the type of the electric device and reference priority classes. In some embodiments, multiple reference priority classes regarding power consumption control may be prepared and stored in memory 460 or cloud system 120. Each of the multiple reference priority classes may correspond to at least one electric device type and be associated with the at least one electric device type.

By way of example, but not limitation, the multiple reference priority classes may include five reference priority classes, e.g., ‘high+priority’, ‘high priority’, ‘normal priority’, ‘low+priority’ and ‘low priority’, each of which is associated with each device type. The ‘high+priority’ class may correspond to a type 1 of an electric device such as a medical device, which requires using electric power continuously. The ‘high priority’ class may correspond to a type 2 of an electric device such as a communication device, which requires using electric power as long as electric power is supplied. The ‘normal priority’ class may correspond to a type 3 of an electric device such as an air conditioner, which permits to reduce electric power consumption. The ‘low+priority’ class may correspond to a type 4 of an electric device such as a game machine, or a refrigerator, which permits interruption of electric power consumption for a certain period according to a user's notification. The ‘low priority’ class may correspond to a type 5 of an electric device such as an illumination, which permits to stop supplying electric power.

By way of example, but not limitation, if device type determining unit 430 determines a type of an electric device as a medical device which corresponds to the type 1, priority class determining unit 450 may determine the priority class of the electric device as the ‘high+priority’. Further, if device type determining unit 430 determines the type of the electric device as a lighting stand which corresponds to the type 5, priority class determining unit 450 may determine the priority class of the electric device as the ‘low priority’.

Memory 460 may be configured to store the obtained pattern of time-series change in the electric power consumption of the electric device as the reference power consumption pattern. Further, memory 460 may be configured to store the multiple reference priority classes regarding power consumption in association with each type of multiple electric devices.

Control unit 470 may be configured to receive a request to control electric power consumption of the electric device. By way of example, but not limitation, control unit 470 may receive a request to control electric power consumption of the electric device from a user who owns or other exercises control over an embodiment of the electric device or an electric power supplier.

Then, control unit 470 may be further configured to control electric power consumption based at least in part on the determined priority class of the electric device. According to the above example, if the type of the electric device is a medical device, when control unit 470 receives a request to control electric power consumption, control unit 470 may be configured to keep on supplying electric power to the electric device since priority class determining unit 450 determined the priority class of the electric device as ‘high+priority’. Further, if the type of the electric device is a lighting stand, control unit 470 may be configured to stop to supply electric power to the electric device since priority class determining unit 450 determined the priority class of the electric device as ‘low priority’.

By way of example, but not limitation, control unit 470 may be configured to control electric power consumption by operating a remote controller that is registered and communicatively coupled to power control system 110.

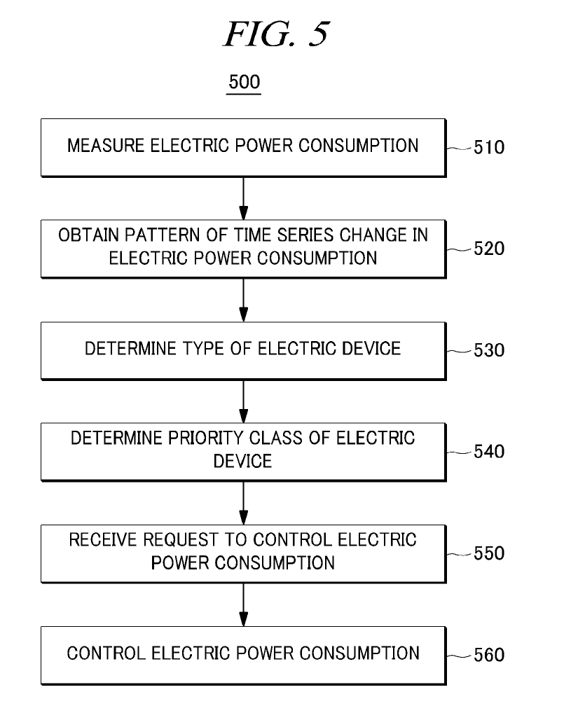

FIG. 5 shows an example flow diagram of a process 500 of power control system 110 for controlling electric power consumption, arranged in accordance with at least some embodiments described herein. The method in FIG. 5 may be implemented in communication environments 100 including power control system 110, cloud system 120, first electric device 130, second electric device 140 and third electric device 150, as illustrated in FIGS. 1. An example process may include one or more operations, actions, or functions as illustrated by one or more blocks 510, 520, 530, 540, 550 and/or 560. Although illustrated as discrete blocks, various blocks may be divided into additional blocks, combined into fewer blocks, or eliminated, depending on the desired implementation. Processing may begin at block 510.

At block 510 (Measure Electric Power Consumption), power control system 110 may be configured to measure electric power consumption of an electric device (e.g., first device 130, second electric device 140, third electric device 150) by using any well-known electric power consumption measuring device such as a wattmeter. Processing may proceed from block 510 to block 520.

At block 520 (Obtain Pattern of Time-Series Change in Electric Power Consumption), power control system 110 may be configured to calculate and obtain a pattern of time-series change in the electric power consumption measured at block 510. The electric power consumption of the electric device may have various types of time-series changed patterns. Non-limiting examples of the time-series changed patterns may include a flat-typed pattern of electric power consumption, which may be obtained from a router, etc, a wave signal-typed pattern of electric power consumption, which may be obtained from a refrigerator, etc, a rectangular pulse-typed pattern of electric power consumption, which may be obtained from a microwave, etc, an environment dependent pattern of electric power consumption, which may be obtained from an air conditioner, etc, or a non-periodic and complex pattern of electric power consumption, which may be obtained from a projector, etc. Processing may proceed from block 520 to block 530.

At block 530 (Determine Type of Electric Device), power control system 110 may be configured to determine a type of the electric device based at least in part on the pattern of time-series change obtained at block 520. In some embodiments, power control system 110 may be configured to compare the obtained pattern of time-series change in the electric power consumption with at least one reference power consumption pattern stored in a local memory of power control system 110. Power control system 110 may be configured to determine the type of the electric device, which is associated with the at least one reference power consumption pattern corresponding to the pattern of time-series change obtained at block 520.

In some other embodiments, at block 530, power control system 110 may be configured to determine the type of the electric device based on at least one reference power consumption pattern stored in cloud system 120.

In some other embodiments, at block 530, power control system 110 may be configured to determine the type of the electric device in consideration of the reference power consumption pattern stored in the local memory of power control system 110 and the reference power consumption pattern stored in cloud system 120 sequentially. Processing may proceed from block 530 to block 540.

At block 540 (Determine Priority Class of Electric Device), power control system 110 may be configured to determine a priority class of the electric device regarding a power consumption control based at least in part on the type of the electric device, which is determined at block 530 and reference priority classes. Multiple reference priority classes regarding power consumption control may be prepared and stored in the local memory or cloud system 120. Each of the multiple reference priority classes may correspond to at least one electric device type and be associated with the at least one electric device type.

By way of example, but not limitation, the multiple reference priority classes may include five reference priority classes, e.g., ‘high+priority’, ‘high priority’, ‘normal priority’, ‘low+priority’ and ‘low priority’, each of which is associated with each device type. The ‘high+priority’ class may correspond to a type 1 of an electric device such as a medical device, which requires using electric power continuously. The ‘high priority’ class may correspond to a type 2 of an electric device such as a communication device, which requires using electric power as long as electric power is supplied. The ‘normal priority’ class may correspond to a type 3 of an electric device such as an air conditioner, which permits to reduce electric power consumption. The ‘low+priority’ class may correspond to a type 4 of an electric device such as a game machine, or a refrigerator, which permits interruption of electric power consumption for a certain period according to a user's notification. The ‘low priority’ class may correspond to a type 5 of an electric device such as a daytime illumination, which permits to stop supplying electric power.

By way of example, at block 530, if the type of the electric device is determined as a medical device which corresponds to the type 1, at block 540, power control system 110 may determine the priority class of the electric device as the ‘high+priority’. Further, at block 530, if the type of the electric device is determined as a lighting stand which corresponds to the type 5, at block 540, power control system 110 may determine the priority class of the electric device as the ‘low priority’. Processing may proceed from block 540 to block 550.

At block 550 (Receive Request to Control Electric Power Consumption), power control system 110 may be configured to receive a request to control electric power consumption of the electric device. By way of example, at block 550, power control system 110 may receive a request to control electric power consumption of the electric device from a user who owns or other exercises control over an embodiment of the electric device or an electric power supplier. Processing may proceed from block 550 to block 560.

At block 560 (Control Electric Power Consumption), power control system 110 may be configured to control electric power consumption based at least in part on the priority class of the electric device, which is determined at block 540. According to the above example, at block 540, if the priority class of the electric device is determined as ‘high+priority’, at block 560, power control system 110 may be configured to keep on supplying electric power to the electric device. Further, at block 540, if the priority class of the electric device is determined as ‘low priority’, at block 560, power control system 110 may be configured to stop to supply electric power to the electric device.

By way of example, but not limitation, at block 560, the electric power consumption may be controlled by operating a remote controller that is registered and communicatively coupled to power control system 110.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

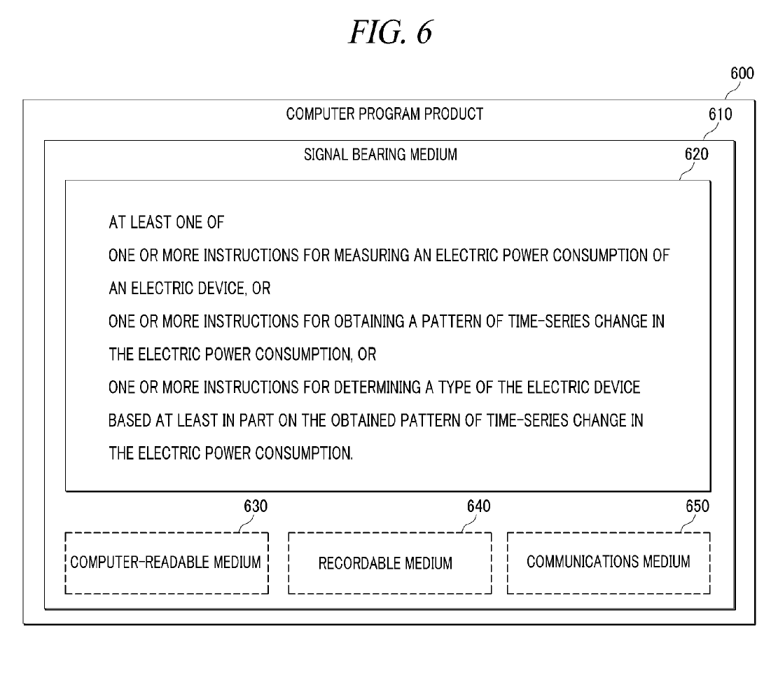

FIG. 6 illustrates computer program products that may be utilized to provide a scheme for controlling electric power consumption, arranged in accordance with at least some embodiments described herein. Program product 600 may include a signal bearing medium 610. Signal bearing medium 610 may include one or more instructions 620 that, when executed by, for example, a processor, may provide the functionality described above with respect to FIGS. 1-4. By way of example, but not limitation, instructions 620 may include: one or more instructions for measuring an electric power consumption of an electric device; one or more instructions for obtaining a pattern of time-series change in the electric power consumption; one or more instructions for determining a type of the electric device based at least in part on the obtained pattern of time-series change in the electric power consumption. Thus, for example, referring to FIG. 5, power control system 110 may undertake one or more of the blocks shown in FIG. 5 in response to instructions 620.

In some implementations, signal bearing medium 610 may encompass a computer-readable medium 630, such as, but not limited to, a hard disk drive, a CD, a DVD, a digital tape, memory, etc. In some implementations, signal bearing medium 610 may encompass a recordable medium 640, such as, but not limited to, memory, read/write (R/W) CDs, R/W DVDs, etc. In some implementations, signal bearing medium 610 may encompass a communications medium 650, such as, but not limited to, a digital and/or an analog communication medium (e.g., a fiber optic cable, a waveguide, a wired communications link, a wireless communication link, etc.). Thus, for example, program product 600 may be conveyed to one or more modules of power control system 110 by an RF signal bearing medium 620, where the signal bearing medium 620 is conveyed by a wireless communications medium 650 (e.g., a wireless communications medium conforming with the IEEE 802.11 standard).

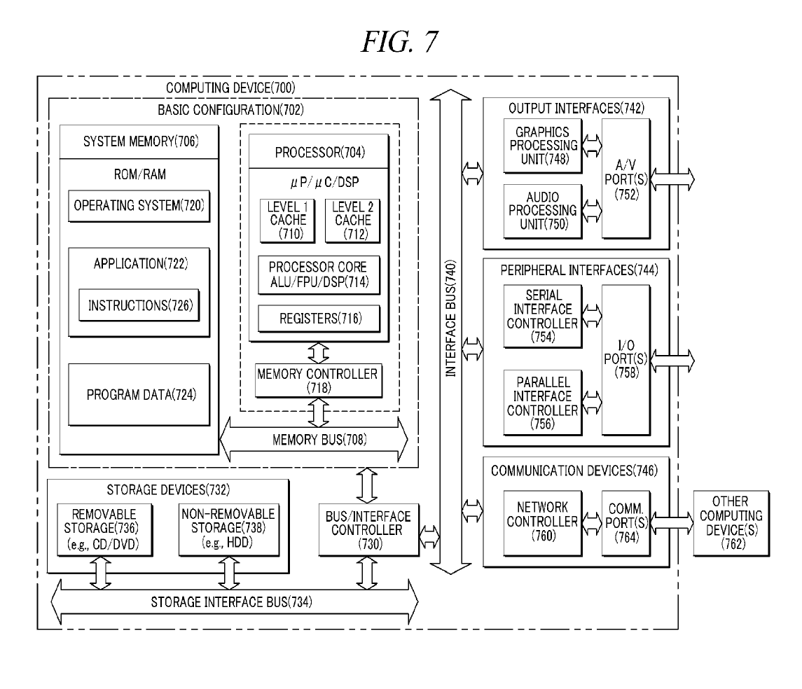

FIG. 7 is a block diagram illustrating an example computing device that may be utilized to provide a scheme for controlling electric power consumption, arranged in accordance with at least some embodiments described herein. In these examples, elements of computing device 700 may be arranged or configured for a device. In a very basic configuration 702, computing device 700 typically includes one or more processors 704 and a system memory 706. A memory bus 708 may be used for communicating between processor 704 and system memory 706.

Depending on the desired configuration, processor 704 may be of any type including but not limited to a microprocessor (μP), a microcontroller (μC), a digital signal processor (DSP), or any combination thereof Processor 704 may include one more levels of caching, such as a level one cache 710 and a level two cache 712, a processor core 714, and registers 716. An example processor core 714 may include an arithmetic logic unit (ALU), a floating point unit (FPU), a digital signal processing core (DSP Core), or any combination thereof An example memory controller 718 may also be used with processor 704, or in some implementations memory controller 718 may be an internal part of processor 704.

Depending on the desired configuration, system memory 706 may be of any type including but not limited to volatile memory (such as RAM), non-volatile memory (such as ROM, flash memory, etc.) or any combination thereof. System memory 706 may include an operating system 720, an application 722, and program data 724. Application 722 may include instructions 726 that may be arranged to perform the functions as described herein including the actions described with respect to power control system architecture as shown in FIG. 4 or including the actions described with respect to the flow charts shown in FIG. 5. In some examples, application 722 may be arranged to operate with program data 724 on an operating system 720 such that the schemes for controlling electric power consumption as described herein may be provided.

Computing device 700 may have additional features or functionality, and additional interfaces to facilitate communications between basic configuration 702 and any required devices and interfaces. For example, a bus/interface controller 730 may be used to facilitate communications between basic configuration 702 and one or more data storage devices 732 via a storage interface bus 734. Data storage devices 732 may be removable storage devices 736, non-removable storage devices 738, or a combination thereof. Examples of removable storage and non-removable storage devices include magnetic disk devices such as flexible disk drives and hard-disk drives (HDD), optical disk drives such as compact disk (CD) drives or digital versatile disk (DVD) drives, solid state drives (SSD), and tape drives to name a few. Example computer storage media may include volatile and nonvolatile, removable and non-removable media implemented in any method or technology for storage of information, such as computer readable instructions, data structures, program modules, or other data.

System memory 706, removable storage devices 736 and non-removable storage devices 738 are examples of computer storage media. Computer storage media includes, but is not limited to, RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which may be used to store the desired information and which may be accessed by computing device 700. Any such computer storage media may be part of computing device 700.

Computing device 700 may also include an interface bus 740 for facilitating communication from various interface devices (e.g., output devices 742, peripheral interfaces 744, and communication devices 746) to basic configuration 702 via bus/interface controller 730. Example output devices 742 include a graphics processing unit 748 and an audio processing unit 750, which may be configured to communicate to various external devices such as a display or speakers via one or more A/V ports 752. Example peripheral interfaces 744 include a serial interface controller 754 or a parallel interface controller 756, which may be configured to communicate with external devices such as input devices (e.g., keyboard, mouse, pen, voice input device, touch input device, etc.) or other peripheral devices (e.g., printer, scanner, etc.) via one or more I/O ports 758. An example communication device 746 includes a network controller 760, which may be arranged to facilitate communications with one or more other computing devices 762 over a network communication link via one or more communication ports 764.

The network communication link may be one example of a communication media. Communication media may typically be embodied by computer readable instructions, data structures, program modules, or other data in a modulated data signal, such as a carrier wave or other transport mechanism, and may include any information delivery media. A “modulated data signal” may be a signal that has one or more of its characteristics set or changed in such a manner as to encode information in the signal. By way of example, and not limitation, communication media may include wired media such as a wired network or direct-wired connection, and wireless media such as acoustic, radio frequency (RF), microwave, infrared (IR) and other wireless media. The term computer readable media as used herein may include both storage media and communication media.

Computing device 700 may be implemented as a portion of a small-form factor portable (or mobile) electronic device such as a cell phone, a personal data assistant (PDA), a personal media player device, a wireless web-watch device, a personal headset device, an application specific device, or a hybrid device that include any of the above functions. Computing device 700 may also be implemented as a personal computer including both laptop computer and non-laptop computer configurations.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, compositions or biological systems, which can, of course, vary. It is also to be understood that the terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A method performed under control of a power control system, comprising:
measuring an electric power consumption of an electric device;
obtaining a pattern of time-series change in the electric power consumption; and
determining a type of the electric device based at least in part on the obtained pattern of time-series change in the electric power consumption.

2. The method of claim 1, further comprising:
storing the obtained pattern of time-series change in the electric power consumption in a local memory of the power control system.

3. The method of claim 1, wherein the determining of the type of the electric device includes comparing the obtained pattern of time-series change in the electric power consumption with at least one reference power consumption pattern stored in a local memory of the power control system.

4. The method of claim 1, further comprising:
storing the obtained pattern of time-series change in the electric power consumption in a cloud data center that is communicatively coupled to the power control system.

5. The method of claim 1, wherein the determining of the type of the electric device includes comparing the obtained pattern of time-series change in the electric power consumption with at least one reference power consumption pattern stored in a cloud data center that is communicatively coupled to the power control system.

6. The method of claim 1, further comprising:
determining a priority class of the electric device regarding a power consumption control based at least in part on the type of the electric device.

7. The method of claim 6, further comprising:
preparing a plurality of reference priority classes of the power consumption control, each reference priority class corresponding to each type of a plurality of electric devices,
wherein the determining of the priority class of the electric device is further based on the plurality of reference priority classes.

8. The method of claim 6, further comprising:
receiving a request to control the electric power consumption of the electric device; and
controlling the electric power consumption of the electric device based at least in part on the determined priority class of the electric device.

9. A power control system, comprising:
an electric power measuring unit configured to measure an electric power consumption of an electric device;
a power consumption pattern obtaining unit configured to obtain a pattern of time-series change in the electric power consumption; and
a device type determining unit configured to determine a type of the electric device based at least in part on the obtained pattern of time-series change in the electric power consumption.

10. The power control system of claim 9, further comprising:
a memory configured to store the obtained pattern of time-series change in the electric power consumption.

11. The power control system of claim 9, further comprising:
a memory configured to store at least one reference power consumption pattern,
wherein the device type determining unit is further configured to compare the obtained pattern of time-series change in the electric power consumption with the at least one reference power consumption pattern.

12. The power control system of claim 9, wherein the device type determining unit is configured to compare the obtained pattern of time-series change in the electric power consumption with at least one reference power consumption pattern stored in a cloud data center that is communicatively coupled to the power control system.

13. The power control system of claim 9, further comprising:
a transceiver configured to transmit the obtained pattern of time-series change in the electric power consumption to a cloud data center that is communicatively coupled to the power control system.

14. The power control system of claim 13, wherein the transceiver is further configured to receive at least one reference power consumption pattern from the cloud data center that is communicatively coupled to the power control system, and
wherein the device type determining unit is further configured to compare the obtained pattern of time-series change in the electric power consumption with the received at least one reference power consumption pattern.

15. The power control system of claim 9, further comprising:
a priority class determining unit configured to determine a priority class of the electric device regarding a power consumption control based at least in part on the type of the electric device.

16. The power control system of claim 15, further comprising:
a memory configured to store a plurality of reference priority classes of the power consumption control in association with each type of a plurality of electric devices,
wherein each reference priority class corresponds to each type of the plurality of electric devices, and
wherein the priority class determining unit is further configured to determine the priority class of the electric device further based on the plurality of reference priority classes.

17. The power control system of claim 15, further comprising:
a control unit configured to:
receive a request to control the electric power consumption of the electric device; and
control the electric power consumption of the electric device based at least in part on the determined priority class of the electric device.

18. A non-transitory computer-readable storage medium having stored thereon computer-executable instructions that, in response to execution, cause a power control system to perform operations, comprising:
measuring an electric power consumption of an electric device;
obtaining a pattern of time-series change in the electric power consumption; and
determining a type of the electric device based at least in part on the obtained pattern of time-series change in the electric power consumption.

19. The computer-readable storage medium of claim 18, wherein the operations further comprise:
preparing a plurality of reference priority classes regarding a power consumption control, each reference priority class corresponding to each type of a plurality of electric devices; and
determining a priority class of the electric device in the power consumption control based at least in part on the type of the electric device and the plurality of reference priority classes.

20. The computer-readable storage medium of claim 19, wherein the operations further comprise:
receiving a request to control the electric power consumption of the electric device; and
controlling the electric power consumption of the electric device based at least in part on the determined priority class of the electric device.
